(19) United States
(12) Patent Application Publication
(10) Pub. No.: US 2026/0255892 A1
(43) Pub. Date: Aug. 27, 2026

(54) SUBSTRATE LIQUID PROCESSING METHOD AND SUBSTRATE LIQUID PROCESSING APPARATUS

(71) Applicant: Tokyo Electron Limited, Tokyo (JP)

(72) Inventors: Yuki FUJII, Kikuchi-gun, Kumamoto (JP); Keiichi FUJITA, Kikuchi-gun, Kumamoto (JP)

(73) Assignee: Tokyo Electron Limited, Tokyo (JP)

(21) Appl. No.: 18/879,484

(22) PCT Filed: Jun. 15, 2023
(86) PCT No.: PCT/JP2023/022267

§ 371 Date: Dec. 27, 2024

(30) Foreign Application Priority Data
Jun. 28, 2022 (JP) 2022-103960

(51) Int. Cl. H10P 14/47; C23C 18/16; C23C 18/18; C23C 18/34; H10P 72/00; H10W 20/00

(52) U.S. Cl. CPC H10P 14/48; C23C 18/1619; C23C 18/1642; C23C 18/1879; C23C 18/34; H10P 72/0411; H10W 20/057

(57) ABSTRACT

A substrate liquid processing method includes preparing a substrate including a wiring and an insulating film provided on the wiring, the insulating film having a recess extending up to the wiring to expose the wiring; performing a pre-cleaning process to clean, by using a pre-cleaning liquid that does not contain a reducing agent but contains a first metal ion, a surface of the insulating film including a partition surface forming the recess; and performing an electroless plating process to precipitate, by using an electroless plating liquid containing the first metal ion, a plating metal in the recess of the substrate after being subjected to the pre-cleaning process.

### TECHNICAL FIELD

The various aspects and embodiments described herein pertain generally to a substrate liquid processing method and a substrate liquid processing apparatus.

### BACKGROUND

Electroless plating may be performed to form a fine wiring on a semiconductor wafer (simply referred to as “wafer”). Patent Document 1 discloses an apparatus configured to fill a via (recess) in a wafer with a metal wiring by performing the electroless plating.

### PRIOR ART DOCUMENT

Patent Document 1: International Publication No. 2019/163531

### DISCLOSURE OF THE INVENTION

### Problems to be Solved by the Invention

Exemplary embodiments provide a technique advantageous in precipitating a plating metal on a substrate in a good condition.

### Means for Solving the Problems

In an exemplary embodiment, a substrate liquid processing method includes preparing a substrate including a wiring and an insulating film provided on the wiring, the insulating film having a recess extending up to the wiring to expose the wiring; performing a pre-cleaning process to clean, by using a pre-cleaning liquid that does not contain a reducing agent but contains a first metal ion, a surface of the insulating film including a partition surface forming the recess; and performing an electroless plating process to precipitate, by using an electroless plating liquid containing the first metal ion, a plating metal in the recess of the substrate after being subjected to the pre-cleaning process.

### Effect of the Invention

According to the exemplary embodiment, it is possible to provide a technique advantageous in precipitating the plating metal on the substrate in a good condition.

### BRIEF DESCRIPTION OF THE DRAWINGS

FIG. 1 is a diagram illustrating a schematic configuration example of a multi-layer wiring forming system.

FIG. 2 is a diagram illustrating a configuration example of an electroless plating device.

FIG. 3 is a diagram illustrating an example of an enlarged cross section of a wafer (particularly, a portion near one recess).

FIG. 4A is a diagram for explaining an example of a substrate liquid processing method according to a first modification example, showing an enlarged cross section of a wafer (particularly, a portion near one recess).

FIG. 4B is a diagram for explaining the example of the substrate liquid processing method according to the first modification example, showing the enlarged cross section of the wafer (particularly, the portion near one recess).

FIG. 4C is a diagram for explaining the example of the substrate liquid processing method according to the first modification example, showing the enlarged cross section of the wafer (particularly, the portion near one recess).

FIG. 4D is a diagram for explaining the example of the substrate liquid processing method according to the first modification example, showing the enlarged cross section of the wafer (particularly, the portion near one recess).

FIG. 4E is a diagram for explaining the example of the substrate liquid processing method according to the first modification example, showing the enlarged cross section of the wafer (particularly, the portion near one recess).

### DETAILED DESCRIPTION

Specific exemplary embodiments of the present disclosure will be described with reference to the accompanying drawings. The following exemplary embodiments are merely examples of a substrate liquid processing method and a substrate liquid processing apparatus that embody the technical concept of the present disclosure, and do not limit the technical sprit of the present disclosure. Individual components in the drawing are shown in simplified forms. It should be noted that the sizes and shapes of the individual components in the drawings and the dimensional ratios therebetween may not necessarily match those of corresponding components in an actual apparatus, and they may not necessarily match between the drawings.

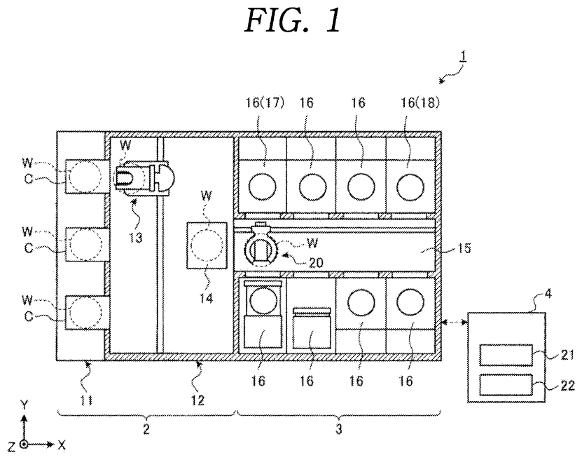

FIG. 1 is a diagram showing a schematic configuration example of a multi-layer wiring forming system 1. In FIG. 1, the X-axis, Y-axis, and Z-axis are perpendicular to each other. The X-axis and the Y-axis extend horizontally, and the positive Z-axis direction is a vertically upward direction.

The multi-layer wiring forming system (substrate liquid processing system) 1 shown in FIG. 1 includes a carry-in/out station 2, a processing station 3, and a control device 4.

The carry-in/out station 2 includes a carrier placement section 11 and a first transfer section 12. A plurality of carriers C is placed in the carrier placement section 11, and each carrier C supports one or more wafers W horizontally. The first transfer section 12 is provided adjacent to the carrier placement section 11, and includes a first substrate transfer device 13 and a delivery module 14.

The first substrate transfer device 13 is configured to transfer the wafer W between each carrier C and the delivery module 14. The first substrate transfer device 13 of the present exemplary embodiment is capable of moving the wafer W horizontally and vertically while holding the wafer W, and is also capable of rotating (pivoting) the wafer W around a vertical axis. The delivery module 14 temporarily supports the wafer W received from the first substrate transfer device 13, or temporarily supports the wafer W to be transferred to the first substrate transfer device 13. The wafer W delivered from the delivery module 14 to the first substrate transfer device 13 is returned from the first substrate transfer device 13 back into the carrier C.

The processing station 3 is provided adjacent to the carry-in/out station 2 (particularly, the first transfer section 12) in the X-axis direction, and includes a second transfer section 15 and a plurality of processing devices 16.

The second transfer section 15 is equipped with a second substrate transfer device 20 configured to be movable along a transfer path. The second substrate transfer device 20 is capable of moving the wafer W horizontally and vertically, and is also capable of rotating (pivoting) the wafer W around a vertical axis. The second transfer section 15 transfers the wafer W received from the delivery module 14 to a required one of the processing devices 16, transfers the wafer W between the processing devices 16, and transfers the wafer W from the processing device 16 to the delivery module 14.

The plurality of processing devices 16 provided in the processing station 3 are arranged on both sides of the transfer path (in the example shown in FIG. 1, the transfer path extending in the X-axis direction) of the second substrate transfer device 20. The layout and the number of these processing devices 16 are not limited to the example shown in FIG. 1, and the processing devices 16 may be arranged in any number and any layout.

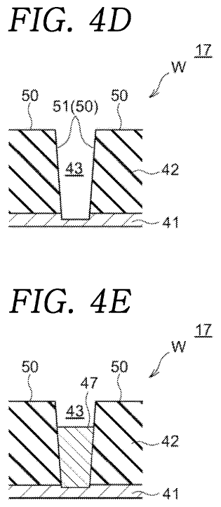

A processing performed in each processing device 16 is not particularly limited basically, but at least one processing device 16 is configured as an electroless plating device (substrate liquid processing device) 17. The electroless plating device 17 performs electroless plating on the wafer W, as will be described later. Further, at least one processing device 16 may be configured as a reverse sputtering device 18 in a first modification example (FIG. 4A to FIG. 4E) to be described later.

As an example, the plurality of processing devices 16 belonging to the processing station 3 may include multiple electroless plating devices 17, multiple chemical mechanical polishing (CMP) processing devices, multiple heat treatment devices, and multiple cleaning devices. The CMP processing device performs a CMP processing on the wafer W. The heat treatment device performs a predetermined heat treatment on the wafer W. The cleaning device performs a cleaning processing on the wafer W, and includes, for example, a spin-clean type cleaner.

The control device 4 is, for example, a computer, and includes a controller 21 and a storage 22. The controller 21 includes a microcomputer having a CPU (Central Processing Unit), a ROM (Read Only Memory), a RAM (Random Access Memory), input/output ports, and so forth, and various types of circuits. The CPU of the microcomputer reads and executes a program stored in the ROM to control the first transfer section 12, the second transfer section 15, and each processing device 16 (including the electroless plating device 17).

The program stored in the storage 22 of the control device 4 may have been recorded on a computer-readable recording medium, and may be installed from that recording medium into the storage 22. The computer-readable recording medium may be, by way of non-limiting example, a hard disk (HD), a flexible disk (FD), a compact disk (CD), a magnet optical disk (MO), and a memory card. The storage 22 may be implemented by, for example, a semiconductor memory device such as a RAM and a flash memory, a storage device such as a hard disk and an optical disk, or the like.

### Electroless Plating Device

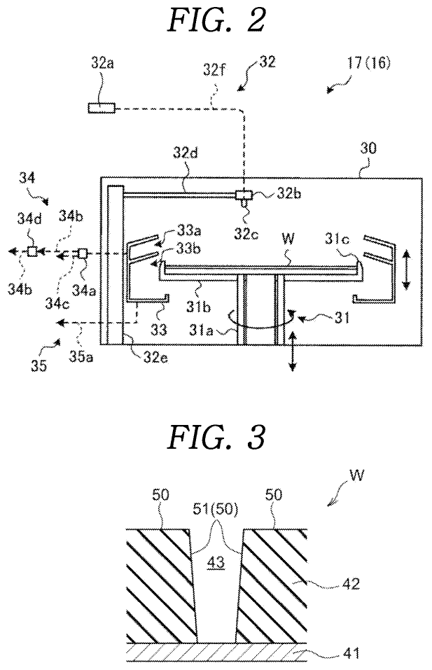

FIG. 2 is a diagram illustrating a configuration example of the electroless plating device 17. FIG. 2 shows a configuration of the inside of a housing 30 in a perspective manner.

The electroless plating device 17 shown in FIG. 2 is configured as a single-wafer processing device 16 configured to process the wafers W one by one, and includes the housing 30, a substrate rotating/holding mechanism 31, a processing liquid supply mechanism 32, and a cup 33 provided at least partially inside the housing 30.

The housing 30 has a non-illustrated openable/closable carry-in/out member. The wafer W transferred by the second substrate transfer device 20 (see FIG. 1) is carried into the housing 30 through the carry-in/out member in an open state, and is carried out from the inside of the housing 30 through the carry-in/out member in the open state. Meanwhile, while the wafer W is undergoing various processes (including electroless plating) within the housing 30 and while no process is being performed in the housing 30, the carry-in/out member is kept in a closed state, so an introduction of the exterior air into the housing 30 is restricted.

The substrate rotating/holding mechanism 31 is configured to hold the wafer W and rotate along with the wafer W. The substrate rotating/holding mechanism 31 has a hollow cylindrical rotation shaft 31a, a turntable 31b, a wafer chuck 31c, and a first rotational driver (not shown). The vertical length of the rotation shaft 31a inside the housing 30 is changed by a second elevating mechanism (not shown), which is driven under the control of the control device 4 (see FIG. 1). The turntable 31b is mounted to an upper end of the rotation shaft 31a. The wafer chuck 31c is provided at an outer peripheral portion of a top surface of the turntable 31b, and is configured to support the wafer W. As the vertical length of the rotation shaft 31a changes, the height positions (vertical positions) of the turntable 31b and the wafer chuck 31c change integrally. The first rotational driver applies a rotational power from a driving source such as a motor to the rotation shaft 31a, thus allowing the rotation shaft 31a, the turntable 31b, and the wafer chuck 31c to be rotated as one body.

The substrate rotating/holding mechanism 31 is operated under the control of the control device 4 (see FIG. 1), and the rotation shaft 31a, the turntable 31b, and the wafer chuck 31c are rotated by the rotational power outputted from the first rotational driver, so that the wafer W supported by the wafer chuck 31c is rotated.

The processing liquid supply mechanism 32 is operated under the control of the control device 4 (see FIG. 1), and supplies a processing liquid (for example, an electroless plating liquid) to a front surface of the wafer W held by the substrate rotating/holding mechanism 31. The processing liquid supply mechanism 32 in the present exemplary embodiment has a processing liquid supply 32a, a discharge head 32b, a discharge nozzle 32c, an arm 32d, a supporting shaft 32e, and a processing liquid supply path 32f.

The processing liquid supply 32a supplies the processing liquid to the discharge head 32b through the processing liquid supplying path 32f. The processing liquid supplied to the discharge head 32b is discharged from the discharge nozzle 32c mounted to the discharge head 32b, and is applied to, for example, a processing surface (top surface) of the wafer W. The discharge head 32b and the discharge nozzle 32c are mounted to a leading end of the arm 32d, and is moved as one body with the arm 32d. The arm 32d is supported by the supporting shaft 32e so as to be movable up and down, and is configured to be movable up and down inside the housing 30. Further, the arm 32d is configured to be rotated (pivoted) together with the supporting shaft 32e so as to be movable horizontally. The supporting shaft 32e is rotated around a central axis extending in a vertical direction by a non-illustrated second rotational driver.

The processing liquid supply mechanism 32 having the above-described configuration can discharge the processing liquid from the discharge nozzle 32c positioned at a required height toward any required position on the processing surface (top surface) of the wafer W.

The cup 33 has two drain ports 33a and 33b disposed at different positions in a vertical direction, and receives the processing liquid scattered from the wafer W. The cup 33 is configured to be movable up and down by a second elevating mechanism (not shown) operated under the control of the control device 4 (see FIG. 1), and the height positions of the two drain ports 33a, 33b are variable. The two drain ports 33a and 33b are connected to liquid draining mechanisms 34 and 35, respectively.

The liquid draining mechanisms 34 and 35 drain the processing liquid collected in the two drain ports 33a and 33b to the outside of the housing 30.

The liquid draining mechanism 34 has a recovery flow path 34b and a waste flow path 34c that are connected to the drain port 33a via a flow path switching device 34a. The flow path switching device 34a switches, between the recovery flow path 34b and the waste flow path 34c, a flow path into which the processing liquid from the drain port 33a can be introduced. The recovery flow path 34b is a flow path through which the processing liquid collected from the drain port 33a is reused, and is provided with a cooling buffer 34d through which the processing liquid is cooled. The waste flow path 34c is a flow path through which the processing liquid collected from the drain port 33a is wasted.

The liquid draining mechanism 35 has a waste flow path 35a connected to the drain port 33b. The waste flow path 35a is a flow path through which the processing liquid collected from the drain port 33b is wasted.

The processing liquid supply 32a is configured to supply an electroless plating liquid and another processing liquid (for example, a cleaning liquid or a rinsing liquid) to the discharge head 32b and the discharge nozzle 32c as the processing liquid. With this configuration, the processing liquid supply mechanism 32 can perform a cleaning process with the cleaning liquid, a rinsing process with the rinsing liquid, or another liquid processing on the wafer W before and after the application of the electroless plating liquid to the wafer W.

In addition, in FIG. 2, the processing liquid supply mechanism 32 is illustrated in a simplified manner, and the one processing liquid supply 32a, the one processing liquid supply path 32f, the one discharge head 32b, and the one discharge nozzle 32c are shown. However, the number and the configuration of the processing liquid supply 32a, the processing liquid supply path 32f, the discharge head 32b, and the discharge nozzle 32c are not limited thereto.

For example, the processing liquid supply 32a, the processing liquid supply path 32f, the discharge head 32b, and/or the discharge nozzle 32c may be provided in plural numbers. In this case, a dedicated processing liquid supply 32a, a dedicated processing liquid supply path 32f, a dedicated discharge head 32b, and/or a dedicated discharge nozzle 32c may be provided for each of multiple types of processing liquids supplied from the processing liquid supply mechanism 32 to the wafer W. Alternatively, a dedicated processing liquid supply 32a, a dedicated processing liquid supply path 32f, a dedicated discharge head 32b, and/or a dedicated discharge nozzle 32c may be provided only for one or more specific types of processing liquids. In this case, the processing liquid supply 32a, the processing liquid supply path 32f, the discharge head 32b, and/or the discharge nozzle 32c are shared for the other types of processing liquids.

### Electroless Plating

Through intensive research, the inventors of the present application have newly found out that, by using a cleaning liquid not containing a reducing agent but containing a first metal ion in the cleaning of the wafer W performed before the application of the electroless plating liquid, a quality of a plating metal deposited in the subsequent electroless plating process can be improved. Here, the “first metal ion” refers to a metal ion contained in the electroless plating liquid as well, such as a metal ion derived from Co (cobalt), W (tungsten) or Ru (ruthenium).

In general, an electroless plating reaction (particularly, precipitation growth of the plating metal) is affected by a wiring pattern layout (especially, wiring pattern density) on the wafer W. That is, the higher the density of multiple recesses (for example, vias or trenches) where the plating metal is to be precipitated by the electroless plating, the easier it tends to be for the plating metal to precipitate with high quality, and the lower the density of the multiple recesses, the more difficult it tends to be for the plating metal to precipitate.

Therefore, when the electroless plating is performed under certain conditions, the plating metal may be properly precipitated in multiple recesses that are provided at high density, but may not be properly precipitated in multiple recesses that are provided at low density. Therefore, when wirings of various pattern densities are formed on the single wafer W by the electroless plating, although the wiring in an area with high pattern density may be formed properly, the wiring in an area with low pattern density may not be properly formed.

The inventors of the present application have actually conducted an electroless plating process to form “a wiring of high pattern density” and “a wiring of low pattern density” on the wafer W. To elaborate, a wafer W having multiple recesses (vias) at bottoms of which a Cu (copper) wiring is exposed is prepared, and the electroless plating process is performed to precipitate a Co plating in the recesses.

As a result, in the recesses where the pattern density is high, the growth (precipitation) of the Co plating from the surface of the underlying Cu wiring is observed. In the recesses where the pattern density is low, however, the growth (precipitation) of the Co plating is not observed.

Through trials and errors, the inventors of the present application have found out that one of the reasons for this difference in the electroless plating reaction depending on the wiring pattern density is that organic component residues such as etching residues tend to be easily deposited in the area of the wafer W with lower pattern density than in the area with higher pattern density.

That is, the inventors of the present application have found out that due to a processing (for example, etching) performed on the wafer W prior to the electroless plating process, the residues tend to be accumulated in the area of the wafer W with lower pattern density than in the area with higher pattern density. Since the residues on the wafer W are a factor that inhibits the growth of the plating metal, it is deemed the growth of the plating metal tends to be slowed or inhibited in the area of the wafer W with the lower pattern density than in the area with the higher pattern density.

The inventors of the present application have confirmed that it is difficult to remove such etching residues (for example, organic component residues) deposited on the wafer W by a typical alkaline cleaning process or a pre-clean process for removing an oxide on the wafer W.

After further trials and errors, the inventors of the present application have also found out that such etching residues can be effectively removed by cleaning the wafer W with a cleaning liquid that contains the same metal ion as the metal ion contained in the electroless plating liquid.

The inventors of the present application have confirmed that by performing the electroless plating after cleaning the wafer W with the cleaning liquid containing such metal ions, the wiring can be appropriately formed in the recesses (vias) both in the area of the wafer W with high pattern density and in the area of the wafer W with low pattern density.

Specifically, after a processing surface of the wafer W having the multiple recesses at the bottoms of which the Cu wiring is exposed is cleaned with a cleaning liquid mainly containing Co and W, the electroless plating is performed to precipitate a CoWB plating in the recesses. As a result, appropriate growth (precipitation) of the CoWB plating from the surface of the underlying Cu wiring is observed, regardless of the wiring pattern density (that is, both in the area of the wafer W with high pattern density and in the area of the wafer W with low pattern density).

As stated above, it is found out that by using the cleaning liquid mainly containing Co and W, the etching residues (CF (fluorocarbon), etc.) on the wafer W can be washed away to be appropriately removed from the wafer W.

The inventors of the present application have also conducted another experiment in which after the processing surface of the wafer W is cleaned with a different cleaning liquid that does not contain Co and W, the electroless plating is performed to precipitate the CoWB plating in the recesses of the processing surface. The cleaning liquid used in the another experiment has the same pH and TMAH (tetramethylammonium hydroxide) concentration as those of the “cleaning liquid mainly containing Co and W” used in the above-described experiment.

In the another experiment where the cleaning liquid not containing Co and W is used to clean the wafer W, the etching residues on the wafer W cannot be properly removed, and the CoWB plating has not grown (has not been precipitated) in the recesses of the wafer W where the pattern density is low. As seen from this result of the another experiment as well, in the cleaning of the wafer W performed prior to the electroless plating, using the cleaning liquid containing the metal ion components (specifically, Co and W) contained in the electroless plating liquid is effective in accomplishing successful electroless plating.

The inventors of the present application have carried out the following experiments to verify the above-stated findings.

That is, the inventors of the present application have investigated a state of the processing surface of the wafer W after being subjected to the etching processing and a state of the growth of the plating metal on the processing surface of the wafer W after being subjected to the etching processing. To elaborate, an etching process (SiCN etching process) is performed on a SiCN film (insulating film) provided on a processing surface of a blanket wafer made of Cu, and an electroless plating process is then performed to precipitate a CoWB plating metal on the processing surface. Also, under the same conditions, the electroless plating process is performed on the processing surface of the blanket wafer made of Cu without performing the SiCN etching process.

Here, the “Cu blanket wafer subjected to the SiCN etching process” simulates an exposed surface of the Cu wiring exposed at the bottom of each recess formed in the insulating film of the wafer W, after being subjected to the etching process. Meanwhile, the “Cu blanket wafer not subjected to the SiCN etching process” simulates the exposed surface of the Cu wiring that is not affected by the etching process at all.

As a result, from a scanning electron microscope (SEM) image, an abnormal layer is found on the wafer processing surface (Cu surface) after being subjected to the SiCN etching process, but no such an abnormal layer is observed on the wafer processing surface (Cu surface) not subjected to the SiCN etching process.

The abnormal layer is caused by the residues resulting from the etching process, and this abnormal layer is observed as a portion having an irregular surface shape (surface state) in the SEM image. Meanwhile, the wafer processing surface (that is, the Cu surface without having the abnormal layer) not subjected to the SiCN etching process is observed as a portion having a flat surface shape in the SEM image.

Also, it is observed from the SEM image that the thickness of the layer of the CoWB plating metal deposited on the wafer processing surface after being subjected to the SiCN etching process is equivalent to about 60% of the thickness of the layer of the CoWB plating metal deposited on the wafer processing surface that has not been subjected to the SiCN etching process.

These results show that the etching process (more specifically, the abnormal layer formed on the wafer processing surface by the etching process) inhibits the growth of the plating metal in the electroless plating.

Also, the inventors of the present disclosure have performed a SiCN etching process, a DIW cleaning process, an IPA cleaning process, a DIW cleaning process, a pre-clean process, a DIW cleaning process, and an IPA cleaning process in sequence on the processing surface of the wafer W.

Here, the DIW cleaning process is a process of supplying deionized water (DIW) to the wafer processing surface to wash it. The IPA cleaning process is a process of supplying isopropyl alcohol (IPA) to the wafer processing surface to wash it. The pre-clean process is a process of supplying a pre-cleaning liquid for removing an oxide to the wafer processing surface to wash it. Each of the DIW cleaning process, the IPA cleaning process, and the pre-clean process is performed for about one minute.

As a result, in an SEM image, although no abnormal layer is found in the area of the wafer processing surface where the wiring pattern density is high, an abnormal layer is observed in the area of the wafer processing surface where the wiring pattern density is low.

As can be seen from these results, it is difficult to remove the etching residues that might cause the abnormal layer on the wafer processing surface by performing typical cleaning processes (that is, the DIW cleaning process, the IPA cleaning process, and the pre-clean process).

Further, the inventors of the present application have also performed a SiCN etching process, a DIW cleaning process, an IPA cleaning process, a DIW cleaning process, a pre-clean process, a pre-cleaning process, a DIW cleaning process, and an IPA cleaning process sequentially on the processing surface of the wafer W. Also, as will be described later, after these cleaning processes, an electroless plating process is performed to precipitate a CoWB plating metal.

Here, the pre-cleaning process is a process of supplying a pre-cleaning liquid to the wafer processing surface to wash the wafer processing surface.

The inventors of the present application have prepared four types of pre-cleaning liquids (first to fourth pre-cleaning liquids) containing different components, and have performed verifications by using these pre-cleaning liquids separately.

The first pre-cleaning liquid contains cobalt sulfate heptahydrate, tungstic acid, citric acid monohydrate, and TMAH, and does not contain any reducing agent. The second pre-cleaning liquid contains cobalt sulfate heptahydrate, citric acid monohydrate, and TMAH, and contains neither tungstic acid nor a reducing agent. The third pre-cleaning liquid contains citric acid monohydrate and TMAH, and does not contain cobalt sulfate heptahydrate, tungstic acid, and a reducing agent. The fourth pre-cleaning liquid contains TMAH, and does not contain cobalt sulfate heptahydrate, tungstic acid, citric acid monohydrate, and reducing agents.

Each of the DIW cleaning process, the IPA cleaning process, and the pre-clean process is performed for about 1 minute. Meanwhile, the pre-cleaning process is performed for about 10 minutes.

As a result, in a SEM image, no abnormal layer is observed on the wafer processing surface that has been subjected to the pre-cleaning process with the first pre-cleaning liquid.

Meanwhile, slightly abnormal layers are observed on the wafer processing surface subjected to the pre-cleaning process with the second pre-cleaning liquid and the wafer processing surface subjected to the pre-cleaning process with the third pre-cleaning liquid. In particular, the degree of abnormality of the abnormal layer on the wafer processing surface pre-cleaned with the third pre-cleaning liquid is found to be slightly higher than the degree of abnormality of the abnormal layer on the wafer processing surface pre-cleaned with the second pre-cleaning liquid.

In addition, a significantly abnormal layer is observed on the wafer processing surface that has been subjected to the pre-cleaning process with the fourth pre-cleaning liquid.

As can be seen from these results, by cleaning the wafer W with a cleaning liquid containing the same metal ions (specifically, Co ions and/or W ions) as those contained in the electroless plating liquid, the etching residues can be removed, so that the generation of the abnormal layer can be effectively suppressed.

The inventors of the present application have also performed the electroless plating process on the processing surface of the wafer W after performing the SiCN etching process, the DIW cleaning process, the IPA cleaning process, the DIW cleaning process, the pre-clean process, the pre-cleaning process, the DIW cleaning process, and the IPA cleaning process as described above.

The inventors of the present application have carried out verifications by using pre-cleaning liquids (the first to fourth pre-cleaning liquids mentioned above) containing different components. In particular, for the second pre-cleaning liquid containing the cobalt sulfate heptahydrate, the citric acid monohydrate and the TMAH, the inventors have performed verifications by using multiple second pre-cleaning liquids with different concentrations of the cobalt sulfate heptahydrate.

Here, however, all of the pre-cleaning liquids used (the first to fourth pre-cleaning liquids) have approximately the same pH (alkalinity). Further, all the pre-cleaning liquids used contain approximately the same concentration of the TMAH. Also, all the first to third pre-cleaning liquids used contain approximately the same concentration of the citric acid.

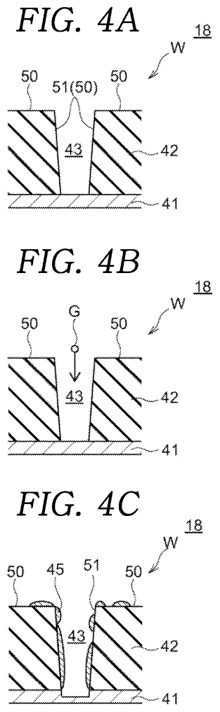

FIG. 3 is a diagram illustrating an example of an enlarged cross section of the wafer W (particularly, a portion thereof near one recess 43).

Specifically, the inventors of the present application have carried out a substrate liquid processing method including a pre-cleaning process and an electroless plating process in the following sequence:

First, a wafer W (substrate) having a wiring (Cu-containing wiring) 41 and an insulating film (SiCN film) 42 provided on the wiring 41 is prepared, and the wafer W is supported by the substrate rotating/holding mechanism (substrate support) 31 of the electroless plating device 17 (see FIG. 2). The insulating film 42 has a multiple number of recesses 43. Each recess 43 extends up to the wiring 41, exposing the wiring 41 at a bottom thereof.

Thereafter, the aforementioned pre-cleaning liquid is supplied to the wafer W from the processing liquid supply mechanism (substrate cleaning device) 32 of the electroless plating device 17 (see FIG. 2), and cleaning (pre-cleaning) of a processing surface of the wafer W is performed with the pre-cleaning liquid. The processing surface of the wafer W that is subjected to the pre-cleaning includes a surface 50 (particularly, a surface 51 that forms each recess 43) of the insulating film 42. The pre-cleaning process is performed by using the pre-cleaning liquid that is heated, specifically, the pre-cleaning liquid heated to 55° C. or higher (e.g., about 80° C.).

Thereafter, an electroless plating liquid is supplied from the processing liquid supply mechanism (electroless plating device) 32 of the electroless plating device 17 (see FIG. 2) to the wafer W after being subjected to the above-described pre-cleaning process, so that the electroless plating process is performed to precipitate a plating metal in each recess 43.

The electroless plating liquid actually used contains cobalt sulfate heptahydrate, tungstic acid, citric acid monohydrate, TMAH, and dimethylamine borane (DMAB) (reducing agent) to precipitate a CoWB plating metal. The electroless plating process is carried out by using the electroless plating liquid heated, specifically, the electroless plating liquid heated to about 40° C. or higher (e.g., about 65° C.).

The inventors of the present application have measured the film thickness of the plating metal (CoWB) deposited on the wafer processing surface subjected to the above-described pre-cleaning and electroless plating processes.

As a result, on the wafer processing surface pre-cleaned with the third or fourth pre-cleaning liquid that does not contain metal ions derived from Co and W, the film thickness of the plating metal is found to be very small both in an area with high pattern density and in an area with low pattern density, and most of the plating metal is not deposited.

Meanwhile, on the wafer processing surface pre-cleaned with the first or second pre-cleaning liquid containing the metal ions derived from Co and/or W, a plating metal having a larger film thickness than that on the wafer processing surface pre-cleaned with the third or fourth pre-cleaning liquid is formed. In particular, on the wafer processing surface pre-cleaned with the first pre-cleaning liquid containing metal ions derived from Co and W, the plating metal is deposited in an approximately same and sufficient film thickness both in the area with high pattern density and in the area with low pattern density.

On the wafer processing surface pre-cleaned with the second pre-cleaning liquid, when the concentration of the cobalt sulfate in the second pre-cleaning liquid is low (specifically, when the concentration of the cobalt sulfate is lower than that of the first pre-cleaning liquid), the film thickness of the plating metal is found to be small. Meanwhile, when the concentration of the cobalt sulfate in the second pre-cleaning liquid is high (specifically, when the concentration of the cobalt sulfate is equal to or higher than that of the first pre-cleaning liquid), the plating metal of the sufficient film thickness is deposited on the wafer processing surface pre-cleaned with the second pre-cleaning liquid. However, when the concentration of the cobalt sulfate in the second pre-cleaning liquid is high, the film thickness of the plating metal deposited on the wafer processing surface is slightly larger in the area with high pattern density than in the area with low pattern density.

The inventors of the present application have performed verifications while varying a time (pre-cleaning time) during which the wafer processing surface is immersed in the pre-cleaning liquid in the pre-cleaning process with the above-described first or second pre-cleaning liquid. As a result, for all the wafer processing surfaces pre-cleaned with the first or second pre-cleaning liquid, the longer the pre-cleaning time, the larger the film thickness of the plating metal deposited on the wafer processing surface.

As can be seen from these results, by performing the pre-cleaning process with the pre-cleaning liquid containing the same metal ions (specifically, Co and W) as those of the electroless plating liquid but not containing any reducing agent, the quality of the subsequent electroless plating process is improved. In particular, by setting the pre-cleaning time to be sufficiently long, organic component residues (CF residues, etc.) on the wafer processing surface are sufficiently removed, and the quality of the subsequent electroless plating process is significantly improved.

As explained above, by performing the pre-cleaning process with the pre-cleaning liquid not containing any reducing agent but containing the same metal ions (specifically, the ions derived from Co and/or W) as those of the electroless plating liquid, the etching residues can be effectively removed from the wafer processing surface. As a result, in the subsequent electroless plating process, the plating metal (CoWB plating metal) can be deposited on the wafer processing surface with high quality and high efficiency.

In particular, it is desirable that the plating metal deposited on the wafer processing surface by the electroless plating process contains a metal obtained from a reduction of a metal ion (first metal ion) contained in the pre-cleaning liquid. In this case, acceleration of an electroless plating reaction is expected, so that a deposition rate and a film thickness growth rate of the plating metal on the wafer processing surface can be improved.

The pre-cleaning liquid and the electroless plating liquid described above are nothing more than examples, and the compositions of the pre-cleaning liquid and the electroless plating liquid are not particularly limited. Further, the metal ion (first metal ion) contained in both the pre-cleaning liquid and the electroless plating liquid is not particularly limited, either. Therefore, the plating metal deposited on the wafer processing surface by the electroless plating process is not particularly limited, either. By way of non-limiting example, at least one of cobalt, nickel, and ruthenium may be included in the plating metal.

Furthermore, the plating metal and the wiring 41 may contain a common metal component. For example, an electroless plating liquid containing a copper-derived ion may be applied to the wiring 41 of copper exposed at the bottom of the recess 43 of the wafer W to deposit a copper plating. Also, as will be described later, an electroless plating liquid containing a ruthenium-derived ion may be applied to the wiring 41 of ruthenium exposed at the bottom of the recess 43 of the wafer W to deposit a ruthenium plating.

Besides, the wiring 41 may contain a metal that exhibits a higher ionization tendency than the metal obtained from the reduction of the metal ion (first metal ion) commonly contained in the pre-cleaning liquid and the electroless plating liquid. In this case, it is expected that a portion of the wiring 41 exposed in the recess 43 will be easily dissolved in the pre-cleaning liquid during the pre-cleaning process, so the exposed surface of the wiring 41 will be turned into a fresher state.

In the above-described exemplary embodiment, the pre-cleaning process and the electroless plating process are performed in the same processing device 16 (i.e., the electroless plating device 17). Alternatively, however, they may be performed in different processing devices 16. Also, the pre-cleaning process and the electroless plating process may be performed in the same substrate liquid processing system (multi-layer wiring forming system 1), or may be performed in different substrate liquid processing systems.

From the viewpoint of performing the electroless plating process with high quality, it is desirable to shorten an elapsed time between the pre-cleaning process and the electroless plating process, to shorten a moving distance of the wafer W, and to suppress exposure of the wafer W to the exterior atmosphere, which may contain foreign matters such as dust. Therefore, it is desirable that the pre-cleaning process and the electroless plating process are performed in the same processing device 16, and it is particularly desirable that the pre-cleaning process and the electroless plating process are performed while the openable/closable carry-in/out member of the processing device 16 is kept closed.

In addition, if the pre-cleaning process and the electroless plating process are performed in the same substrate liquid processing system, rather than in separate substrate liquid processing systems, the quality of the plating metal deposited on the wafer W by the electroless plating process can be improved.

The substrate liquid processing system referred to here may refer to an overall system that includes the carry-in/out station 2 and the processing station 3, as shown in FIG. 1, for example. In a certain substrate liquid processing system, after the wafer W is transferred from the carry-in/out station 2 to the processing station 3, the wafer W may be subjected to the pre-cleaning process and the electroless plating process as described above in one or more processing devices 16 of the processing station 3 without being returned to the carry-in/out station 2. In this case, the wafer W may be returned back to the carry-in/out station 2 after being subjected to the pre-cleaning process and the electroless plating process.

### First Modification Example

The substrate liquid processing method of the above-described exemplary embodiment may include a process of removing the wiring 41 exposed in the recess 43 of the wafer W before the pre-cleaning process is performed. Any of various methods may be adopted to remove the wiring 41 exposed in the recess 43 of the wafer W. For example, reverse sputtering may be performed.

FIG. 4A to FIG. 4E are diagrams for describing an example of a substrate liquid processing method according to a first modification example, and show an enlarged cross section of the wafer W (particularly, a portion near one recess 43).

First, the wafer W having the wiring 41 and the insulating film 42 provided on the wiring 41 is placed in a reverse sputtering device 18 (processing device 16 (see FIG. 1)) (see FIG. 4A). The insulating film 42 has the multiple number of recesses 43, and each of the recesses 43 extends up to the wiring 41, so the wiring 41 is exposed at the bottom of the recess 43.

The wafer W is then subjected to a reverse sputtering process in the reverse sputtering device 18. That is, using the wafer W as a target, the reverse sputtering device 18 applies a high voltage to the wafer W to generate a glow discharge, and ionizes a reverse sputtering gas G fully filled around the wafer W, causing it to collide with the wiring 41 exposed in the recess 43 (see FIG. 4B).

As a result, as illustrated in FIG. 4C, the exposed surface of the wiring 41 in the recess 43 is blown away by the reverse sputtering gas G, and a fresh surface (new surface) of the wiring 41 is exposed at the bottom of the recess 43. Meanwhile, the portion of the wiring 41 blown away by the reverse sputtering gas G (i.e., a reverse sputtered metal 45) adheres to the surface 50 of the insulating film 42 (including the surface 51 forming the recess 43).

Specific equipment of the reverse sputtering device 18 is not particularly limited. For example, the reverse sputtering device 18 can perform the above-described reverse sputtering process by using an existing sputtering device equipped with a voltage application device and a reverse sputtering gas supply device. A specific composition of the reverse sputtering gas G is not particularly limited, either. By way of example, although argon may be used as the reverse sputtering gas G, any of various other gases (for example, a rare gas element other than argon or nitrogen) may be used.

Thereafter, the wafer W is placed in the electroless plating device 17 (processing device 16 (see FIG. 1)).

Then, the wafer W is subjected to the above-described pre-cleaning process in the electroless plating device 17, so that the reverse sputtered metal 45 attached to the surface 50 of the insulating film 42 is removed (FIG. 4D). That is, the reverse sputtered metal 45 is removed from the wafer W by the pre-cleaning process with the pre-cleaning liquid not containing the reducing agent but containing the metal ion (for example, the ion derived from Co and/or W (first metal ion)) contained in the electroless plating liquid as well.

Further, the wiring 41 may contain a metal that exhibits a higher ionization tendency than a metal obtained from the reduction of the metal ion (first metal ion) contained in both the pre-cleaning liquid and the electroless plating liquid. In this case, the exposed surface of the wiring 41 at the bottom of the recess 43 may be dissolved in the pre-cleaning liquid by the pre-cleaning process, thereby exposing a fresher surface of the wiring 41 at the bottom of the recess 43.

Afterwards, the wafer W is subjected to the above-described electroless plating process in the electroless plating device 17, so that a plating metal 47 is deposited in each recess 43. The plating metal 47 may have the same composition (for example, ruthenium) as the wiring 41 or may have a composition different from that of the wiring 41.

According to the present modification example, before the pre-cleaning process is performed, the wiring 41 exposed in the recess 43 of the wafer W is removed to expose the fresh surface of the wiring 41 at the bottom of the recess 43. This can improve reactivity in the subsequent electroless plating process.

In particular, in the pre-cleaning process, by using the pre-cleaning liquid that does not contain the reducing agent but contains the metal ion (first metal ion) contained in the electroless plating liquid as well, the reverse sputtered metal 45 adhering to the surface 50 of the insulating film 42 can be effectively removed. Therefore, in the subsequent electroless plating process, the growth of the plating metal from the surface 50 (for example, the surface 51) of the insulating film 42 to which the reverse sputtered metal 45 is attached can be suppressed, while allowing the plating metal to grow from the bottom of the recesses 43.

As a result, the plating metal can be precipitated in a bottom-up manner in each recess 43, so a defect such as formation of a void can be suppressed, and a high-quality wiring (plating metal 47) can be formed in each recess 43.

The inventors of the present application have performed verifications for the above-described effects obtained by the present modification example.

That is, multiple wafers W after being subjected to the above-described reverse sputtering process (see FIG. 4A to FIG. 4C) are prepared. Some of these wafers W are subjected to the above-described pre-cleaning process (see FIG. 4D) and then to the electroless plating process (see FIG. 4E). Meanwhile, the other wafers W are subjected to the electroless plating process without undergoing the pre-cleaning process (FIG. 4D) (see FIG. 4E).

As a result, it is found from a SEM image that each recess 43 of the wafer W subjected to the electroless plating process after the pre-cleaning process is uniformly filled with plating metal 47.

Meanwhile, each recess 43 of the wafer W subjected to the electroless plating process without undergoing the pre-cleaning process is found to be filled with the plating metal 47 in a non-uniform manner, and the plating metal 47 is also found to be irregularly deposited on the surface 50 of the insulating film 42 around each recess 43.

As can be seen from these results, performing the above-described pre-cleaning process after the reverse sputtering process is advantageous for uniformly and selectively precipitating the plating metal 47 in each recess 43 of the wafer W by the subsequent electroless plating process.

### Other Modification Examples

It will be appreciated that the disclosure in the present specification is illustrative in all aspects and is not intended to be limiting. In the above-described exemplary embodiments and modification examples, various omissions, replacement and modifications may be made without departing from the scope and spirit of the claims. For example, the above-described exemplary embodiments and modification examples may be combined in whole or in part, and exemplary embodiments other than those described above may be combined with the above-described exemplary embodiments or modification examples.

Furthermore, a technical category for embodying the above-described technical concept is not particularly limited. By way of example, the above-described apparatus may be applied to another apparatus. Moreover, the above-described technical concept may be embodied by a computer-executable program for executing one or multiple sequences (processes) included in the above-described method. Further, the above-described technical concept may be embodied by a computer-readable non-transitory recording medium in which such a computer-executable program is stored.

1. A substrate liquid processing method, comprising:
preparing a substrate including a wiring and an insulating film disposed on the wiring, the insulating film having a recess extending up to the wiring to expose the wiring;
performing a pre-cleaning process to clean, by using a pre-cleaning liquid that does not contain a reducing agent but contains a first metal ion, a surface of the insulating film including a partition surface forming the recess; and
performing an electroless plating process to precipitate, by using an electroless plating liquid containing the first metal ion, a plating metal in the recess of the substrate after being subjected to the pre-cleaning process.

2. The substrate liquid processing method of claim 1,
wherein the pre-cleaning process is performed by using the pre-cleaning liquid that is heated.

3. The substrate liquid processing method of claim 1,
wherein the pre-cleaning process is performed by using the pre-cleaning liquid heated to a temperature of 55° C. or higher.

4. The substrate liquid processing method of claim 1,
wherein the plating metal includes a metal obtained from reduction of the first metal ion.

5. The substrate liquid processing method of claim 1,
wherein the plating metal includes at least one of cobalt, nickel, or ruthenium.

6. The substrate liquid processing method of claim 1, wherein the plating metal and the wiring contain a common metal component.

7. The substrate liquid processing method of claim 1,
wherein the wiring contains copper.

8. The substrate liquid processing method of claim 1, further comprising:
removing the wiring exposed in the recess before the pre-cleaning process is performed.

9. The substrate liquid processing method of claim 8,
wherein the removing of the wiring exposed in the recess is performed by performing a reverse sputtering process.

10. The substrate liquid processing method of claim 1,
wherein the wiring contains a metal that exhibits a higher ionization tendency than a metal obtained from reduction of the first metal ion.

11. The substrate liquid processing method of claim 1,
wherein a substrate liquid processing system comprises a carry-in/out station and a processing station,
the substrate is subjected to the pre-cleaning process and the electroless plating process in the processing station without being returned to the carry-in/out station after being sent from the carry-in/out station to the processing station, and
the substrate is returned back to the carry-in/out station after being subjected to the pre-cleaning process and the electroless plating process.

12. The substrate liquid processing method of claim 1,
wherein the pre-cleaning process and the electroless plating process are performed in same processing device.

13. A substrate liquid processing apparatus, comprising:
a substrate support configured to support a substrate including a wiring and an insulating film disposed on the wiring, the insulating film having a recess extending up to the wiring to expose the wiring;
a substrate cleaning device configured to perform a pre-cleaning process by supplying a pre-cleaning liquid, which does not contain a reducing agent but contains a first metal ion, to the substrate to clean a surface of the insulting film including a partition surface forming the recess; and
an electroless plating device configured to precipitate a plating metal in the recess of the substrate after being subjected to the pre-cleaning process by supplying an electroless plating liquid containing the first metal ion to the substrate.

14. The substrate liquid processing apparatus of claim 13, wherein the pre-cleaning process is performed by using the pre-cleaning liquid heated to a temperature of 55° C. or higher.

15. The substrate liquid processing apparatus of claim 13, wherein the plating metal includes a metal obtained from reduction of the first metal ion, and
the plating metal includes at least one of cobalt, nickel, or ruthenium.

16. The substrate liquid processing apparatus of claim 13, wherein the plating metal and the wiring contain a common metal component.

17. The substrate liquid processing apparatus of claim 13, wherein the substrate cleaning device is configured to perform the pre-cleaning process with the wiring removed from the recess.

18. The substrate liquid processing apparatus of claim 13, wherein the wiring contains a metal that exhibits a higher ionization tendency than a metal obtained from reduction of the first metal ion.

19. The substrate liquid processing apparatus of claim 13, further comprising a carry-in/out station and a processing station,
wherein the carry-in/out station includes a transfer device,
the substrate is subjected to the pre-cleaning process and the electroless plating process in the processing station without being returned, by the transfer device, to the carry-in/out station after being sent from the carry-in/out station to the processing station, and
the transfer device is configured to return the substrate back to the carry-in/out station after being subjected to the pre-cleaning process and the electroless plating process.

20. The substrate liquid processing apparatus of claim 13, wherein the pre-cleaning process and the electroless plating process are performed in a same processing device.
